(19) United States
(12) Patent Application Publication
(10) Pub. No.: US 2015/0221537 A1
(43) Pub. Date: Aug. 6, 2015

(54) CONTAINER INTERCHANGING METHOD

(71) Applicant: TOKYO ELECTRON LIMITED, Tokyo (JP)

(72) Inventor: Shinji WAKABAYASHI, Nirasaki City (JP)

(21) Appl. No.: 14/608,843

(22) Filed: Jan. 29, 2015

(30) Foreign Application Priority Data
Feb. 6, 2014 (JP) 2014-021364

(51) Int. Cl. H01L 21/677; H01L 21/673

(52) U.S. Cl. CPC H01L 21/67745; H01L 21/673; H01L 21/67775

(57) ABSTRACT

A container interchanging method is provided. The container interchanging method provides that a first container accommodating a processed substrate therein and a second container accommodating an unprocessed substrate therein are interchanged in a container connection mechanism of a substrate transfer chamber. The substrate transfer chamber includes the container connection mechanism to which the container accommodating the substrate is connected. The substrate transfer chamber is configured to unload the substrate from the container connected to the container connection mechanism. The substrate transfer chamber further includes a buffer configured to mount the container. When the first container and the second container are interchanged in the container connection mechanism, any one of the first container and the second container is temporarily stored in the buffer.

### CROSS-REFERENCE TO RELATED APPLICATION

This application claims the benefit of Japanese Patent Application No. 2014-021364, filed on Feb. 6, 2014, in the Japan Patent Office, the disclosure of which is incorporated herein in its entirety by reference.

### TECHNICAL FIELD

The present disclosure relates to a method of interchanging containers accommodating substrates therein in a container connection mechanism of a substrate processing system.

### BACKGROUND

A substrate processing system configured to perform a plasma process on semiconductor wafers (hereinafter, simply referred to as “wafers”) as substrates includes process modules as plasma process chambers, and a loader module as an atmospheric transfer chamber configured to load and unload wafers into and from a container which accommodates a plurality of wafers therein, such as a FOUP (Front Opening Unified Pod).

In the substrate processing system, a wafer is loaded from the FOUP connected to a container connection mechanism (loading port) of the loader module into the process module via the loader module, a load lock module as an atmosphere-vacuum conversion chamber, and a transfer module as a vacuum transfer chamber.

The substrate processing system generally includes a plurality of process modules in light of the plasma processing efficiency of wafers. Thus, the loader module has a plurality of loading ports, for example, three loading ports, such that the wafers can be simultaneously loaded into the respective process modules. These loading ports are straightly arranged at one side of the loader module having a housing shape.

In such a substrate processing system, when a FOUP having plasma-processed wafers accommodated therein (hereinafter, referred to as a “processed FOUP”) and a FOUP having unprocessed wafers accommodated therein (hereinafter, referred to as a “unprocessed FOUP”) are interchanged in each loading port, container transfer units (Over Head Transfer Units, hereinafter, referred to as “OHTs”), which are moved along a guide rail horizontally disposed above the loader module, are used.

Specifically, first, one of the OHTs moves to a point directly above a loading port and removes the processed FOUP from the corresponding loading port. Then, the OHT is withdrawn from the point directly above the loading port. Thereafter, another OHT which transfers an unprocessed FOUP moves to the point directly above the loading port and disposes the unprocessed FOUP in the loading port.

However, no FOUP is disposed in the loading port after the one OHT is withdrawn from the point directly above the loading port, until the other OHT moves to the point directly above the loading port,. Thus, the loading port does not contribute to the manufacture of semiconductor devices on a semiconductor wafer, thereby deteriorating manufacturing efficiency of the semiconductor devices on the semiconductor wafer.

### SUMMARY

Some embodiments of the present disclosure provide a container interchanging method capable of preventing manufacturing efficiency of semiconductor devices from being deteriorated.

According to one embodiment of the present disclosure, there is provided a container interchanging method, including: when interchanging a first container, into which a processed substrate is accommodated, and a second container, into which an unprocessed substrate is accommodated, in a container connection mechanism of a substrate transfer chamber, the substrate transfer chamber further including a buffer configured to mount the first or second container, storing the first or second container in the buffer temporarily, wherein the substrate transfer chamber includes the container connection mechanism to which the first or second container is connected, the substrate transfer chamber being configured to unload the processed or unprocessed substrate from the first or second container connected to the container connection mechanism.

According to another embodiment of the present disclosure, there is provided a container interchanging method, including: when interchanging a first container, into which a processed substrate is accommodated, and a second container, into which an unprocessed substrate is accommodated, in a container connection mechanism of a substrate transfer chamber, the substrate transfer chamber further including a port configured to receive the first or second container from a container transfer mechanism installed in addition to the substrate transfer chamber, storing the first or second container in the buffer temporarily, wherein the substrate transfer chamber includes the container connection mechanism to which the first or second container is connected, the substrate transfer chamber being configured to unload the processed or unprocessed substrate from the first or second container connected to the container connection mechanism.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a configuration of a substrate processing system in which a container interchanging method according to a first embodiment of the present disclosure is performed.

FIG. 2 is a front view schematically showing a configuration of a loader module in FIG. 1.

FIG. 3 is a side view schematically showing a configuration of the loader module in FIG. 1 as viewed in the arrow direction in FIG. 2.

FIGS. 4A to 6F are process views of a FOUP interchanging method as the container interchanging method according to this embodiment.

FIGS. 7A to 9B are process views of a FOUP interchanging method as a container interchanging method according to a second embodiment of the present disclosure.

FIGS. 10A to 12 are process views of a FOUP interchanging method as a container interchanging method according to a third embodiment of the present disclosure.

FIGS. 13A and 13B are views illustrating an inter-port time difference in a substrate processing system having a plurality of ports, wherein FIG. 13A shows an inter-port time difference in a conventional container interchanging method, and FIG. 13B shows an inter-port time difference in the container interchanging method according to the third embodiment of the present disclosure.

FIG. 14 is a front view schematically showing a configuration of a modification of the loader module.

FIG. 15 is a side view schematically showing a configuration of the modification of the loader module as viewed in the arrow direction in FIG. 14.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a container interchanging method according to a first embodiment of the present disclosure will be described with reference to the drawings.

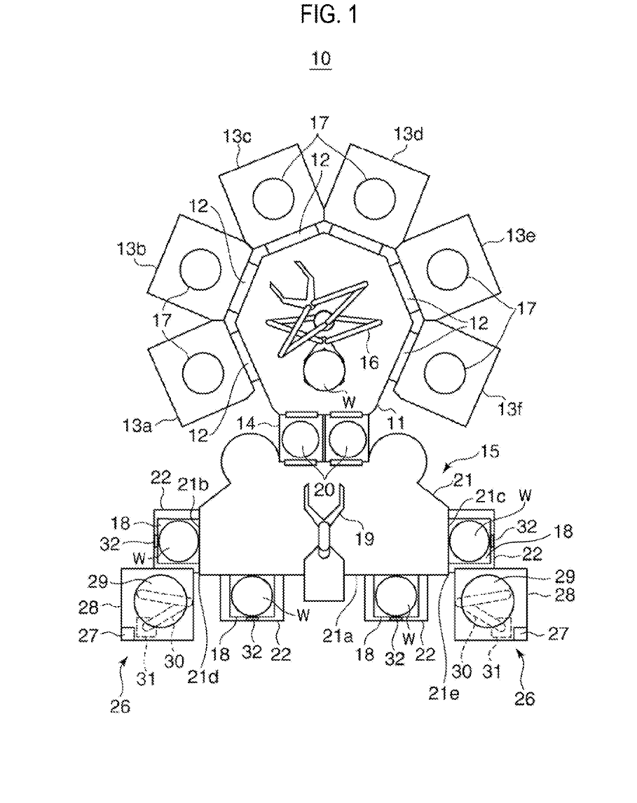

FIG. 1 is a plan view schematically showing a configuration of a substrate processing system in which the container interchanging method according to this embodiment is performed. FIG. 1 shows internal components of the substrate processing system seen therethrough for convenience.

Referring to FIG. 1, a substrate processing system 10 includes a transfer module 11 as a vacuum transfer chamber having a generally heptagonal shape as viewed in a plan view, six process modules 13a to 13f as plasma process chambers connected to the transfer module 11 through gate valves 12 radially arranged around the transfer module 11, two load lock modules 14 as atmosphere-vacuum conversion chambers connected to a side of the transfer module 11 to which any one of the process modules 13a to 13f is not connected, and a loader module 15 as a substrate transfer chamber being opposite to the transfer module 11 via the load lock modules 14 and connected to the load lock modules 14.

The transfer module 11 has a transfer mechanism 16 housed therein to transfer a wafer W between the process modules 13a to 13f and between the process modules 13a to 13f and the respective load lock modules. The interior of the transfer module 11 is pressure-reduced to a predetermined level of vacuum.

Each of the process modules 13a to 13f has one stage 17 for mounting a wafer W thereon. The interior of each process module is pressure-reduced to a predetermined level of vacuum in the same manner as the transfer module 11. In each of the process modules 13a to 13f, a predetermined plasma process, for example, a dry etching process, is performed on the wafer W mounted on the stage 17.

The loader module 15 has a transfer robot 19 housed therein to transfer a wafer W between FOUPs 18 accommodating a plurality of wafers W therein and the respective load lock modules 14. The interior of the loader module 15 is maintained at atmospheric pressure.

Each of the load lock modules 14 has a stage 20 for mounting a wafer W thereon. The interior of each load lock module 14 may be switched between an atmospheric pressure environment and a pressure reduced environment. For example, when the wafer W is transported between the transfer robot 19 of the loader module 15 and the load lock module 14, the interior of the load lock module 14 is switched into the atmospheric pressure environment and communicates with the interior of the loader module 15. Also, when the wafer W is transported between the transfer mechanism 16 of the transfer module 11 and the load lock module 14, the interior of the load lock module 14 is switched into the pressure-reduced environment and communicates with the interior of the transfer module 11. That is, the interior of the load lock module 14 is switched into the atmospheric pressure environment or the pressure-reduced environment to transfer the wafer W between the transfer module 11 and the loader module 15.

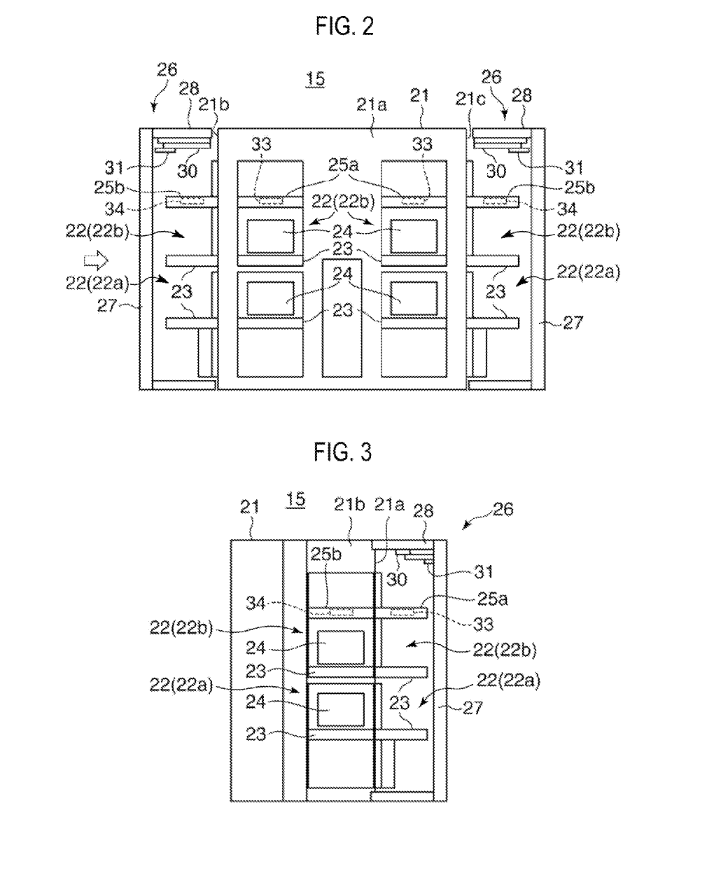

FIG. 2 is a front view schematically showing a configuration of a loader module in FIG. 1, and FIG. 3 is a side view schematically showing a configuration of the loader module in FIG. 1 as viewed in the arrow direction in FIG. 2.

Referring to FIGS. 2 and 3, the loader module 15 has a main body 21 having a modified hexagonal housing shape as viewed in a plan view, and a plurality of loading ports 22 as container connection mechanisms for connecting the FOUPs 18 to the main body 21.

In the loader module 15, the loading ports 22 are arranged to be overlapped in a height direction of the main body 21 (hereinafter, simply referred to as a “height direction”) at a side 21a of the main body 21 opposite to the side to which the load lock modules 14 are connected and two sides 21b and 21c adjacent to the side 21a, respectively. In this embodiment, for convenience, the loading ports 22 are classified into lower loading ports 22a and upper loading ports 22b. Two sets of lower and upper loading ports 22a and 22b are disposed at the side 21a, and a set of lower and upper loading ports 22a and 22b is disposed at each of the sides 21b and 21c, respectively.

Each of the loading ports 22 has a flat plate-shaped stage 23 horizontally protruding from the main body 21, and a FOUP connection port 24 opened in the main body 21 to face the FOUP 18 mounted on the corresponding stage 23. The FOUP connection port 24 is generally closed by a shutter (not shown) or the like. However, when the FOUP 18 is mounted on the stage 23 and connected to the FOUP connection port 24, the FOUP connection port 24 is opened and a lid (not shown) of the FOUP 18 is removed. Thus, the interior of the main body 21 communicates with the interior of the FOUP 18.

A port 25a and a buffer 25b, each configured with a flat plate-shaped stage horizontally protruding, are disposed above each set of the lower and upper loading ports 22a and 22b. Each of the ports 25a and each of the buffers 25b temporally store the FOUP 18 transported by a later-described FOUP transporter 26.

The FOUP 18 has an ID unit (identification unit) 32 consisting of IC chips. The information (hereinafter, referred to as “processing information”) of a plasma process performed on the respective wafers W accommodated in the FOUP 18 is written in the ID unit 32. Each port 25a has an ID reader (reading unit) 33. The ID reader 33 performs a wireless communication with the ID unit 32 of the FOUP 18 temporarily stored in the port 25a to read the processing information written in the ID unit 32. In addition, each buffer 25b has a purge unit 34. The purge unit 34 purges the interior of the FOUP 18 temporarily stored in the buffer 25b, for example, using N₂ gas.

Further, the loader module 15 has the two FOUP transporters 26 respectively disposed opposite to a corner 21d of the main body 21 defined by the sides 21a and 21b (see FIG. 1) and a corner 21e of the main body 21 defined by the sides 21a and 21c (see FIG. 1).

Each of the FOUP transporter 26 has a post 27 installed to be vertically erected in the height direction, a base 28 installed to the post 27 and moved in the height direction, a rotary base 29 disposed in the base 28 and rotated in the horizontal plane, a SCARA (Selective Compliance Assembly Robot) arm 30 installed at a location offset from the center of the rotary base 29, and a coupling part 31 installed at the leading end of the arm 30 to be caught and coupled to an upper portion of the FOUP 18. The FOUP transporter 26 transports the FOUPs 18 between the loading ports 22, the ports 25a and the buffers 25b by a vertical movement of the base 28, a rotation of the rotary base 29, and an extension and retraction of the arm 30.

Subsequently, the container interchanging method according to this embodiment will be described.

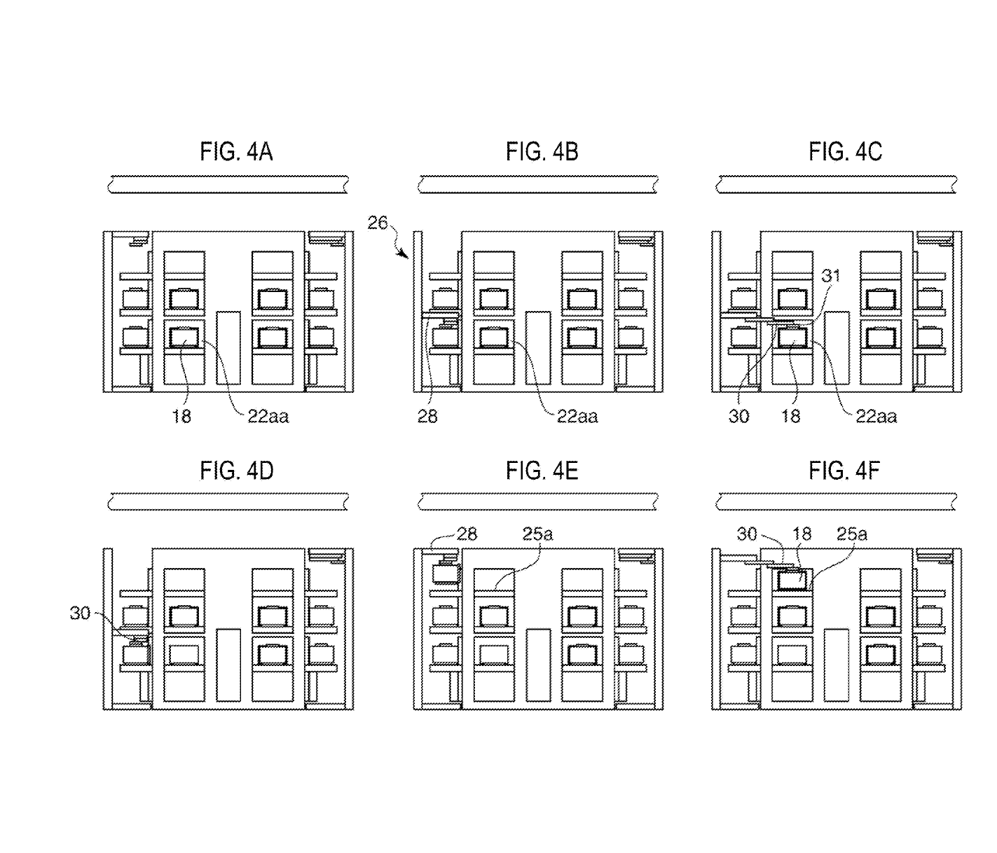

FIGS. 4A to 6F are process views of a FOUP interchanging method as the container interchanging method according to this embodiment. This interchanging method is performed by a cooperation of the FOUP transporter 26 of the loader module 15 and a ceiling container transfer system 36 disposed above the loader module 15.

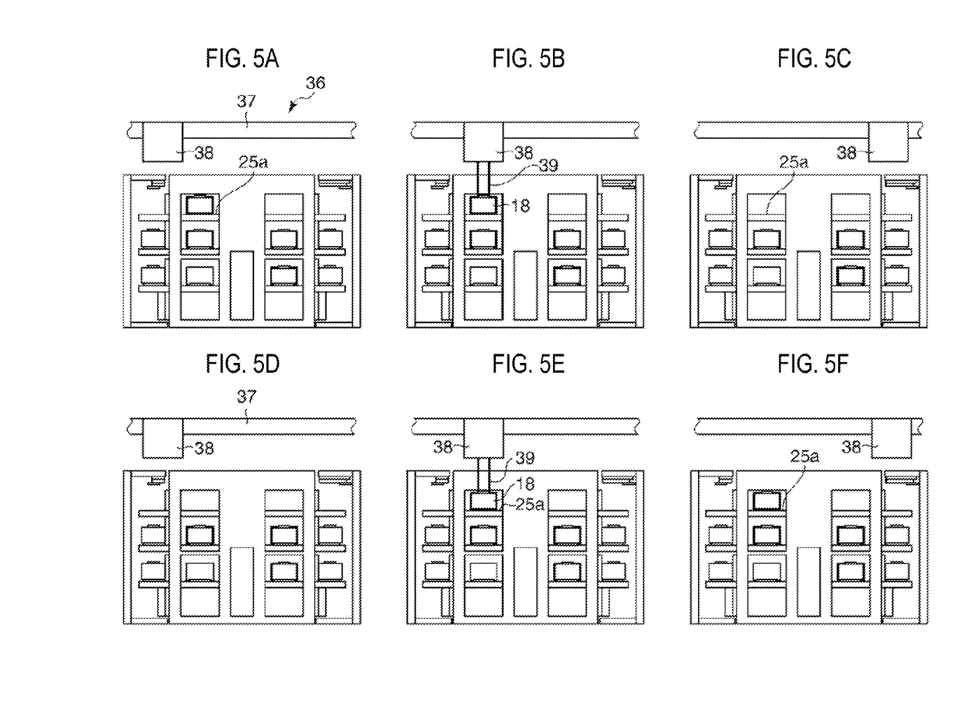

As shown in FIG. 5A and the like, the ceiling container transfer system 36 has a guide rail 37 horizontally disposed above the loader module 15, and an OHT 38 as a container transfer unit moving along the guide rail 37. For example, when a plurality of substrate processing systems 10 are disposed in a clean room, the guide rail 37 is disposed so as to pass above the substrate processing systems 10 and the OHT 38 transports the FOUP 18 to the respective substrate processing systems 10.

In this interchanging method, first, if the plasma process on all the wafers W accommodated in a FOUP 18 connected to the FOUP connection port 24 of a lower loading port 22aa is terminated (FIG. 4A), the base 28 of the FOUP transporter 26 is lowered to the neighborhood of the lower loading port 22aa (FIG. 4B). Then, the arm 30 extends to the FOUP 18 being connected to the FOUP connection port 24 of the lower loading port 22aa and accommodating the wafers W which all have been subjected to the plasma process (hereinafter, referred to as the “processed FOUP 18”) (first container). Then, the coupling part 31 is caught and coupled to the upper portion of the processed FOUP 18 (FIG. 4C).

Then, the arm 30 is retracted (FIG. 4D), the base 28 is raised to the neighborhood of the port 25a (FIG. 4E), and the arm 30 extends to mount the processed FOUP 18 in the port 25a and temporarily stores the processed FOUP 18 in the port 25a (FIG. 4F).

Then, in the ceiling container transfer system 36, the OHT 38 moves along the guide rail 37 (FIG. 5A) and stops at the point above the port 25a. Then, a hoist belt 39 is lowered from the OHT 38 and caught to the upper portion of the processed FOUP 18 (FIG. 5B). The OHT 38 hoists the hoist belt 39, accommodates the processed FOUP 18 therein, and is then withdrawn from the point above the port 25a (FIG. 5C).

Next, the OHT 38 for transferring a FOUP 18 accommodating unprocessed wafers W therein (hereinafter, referred to as an “unprocessed FOUP 18”) (second container) moves along the guide rail 37 (FIG. 5D) and stops at the point above the port 25a. Then, the hoist belt 39 is lowered from the OHT 38 and mounts the unprocessed FOUP 18 in the port 25a to temporarily store the unprocessed FOUP 18 in the port 25a (FIG. 5E).

Thereafter, the OHT 38 hoists the hoist belt 39 and is withdrawn from the point above the port 25a (FIG. 5F). The ID reader 33 of the port 25a reads the processing information written in the ID unit 32 of the unprocessed FOUP 18 temporarily stored in the port 25a.

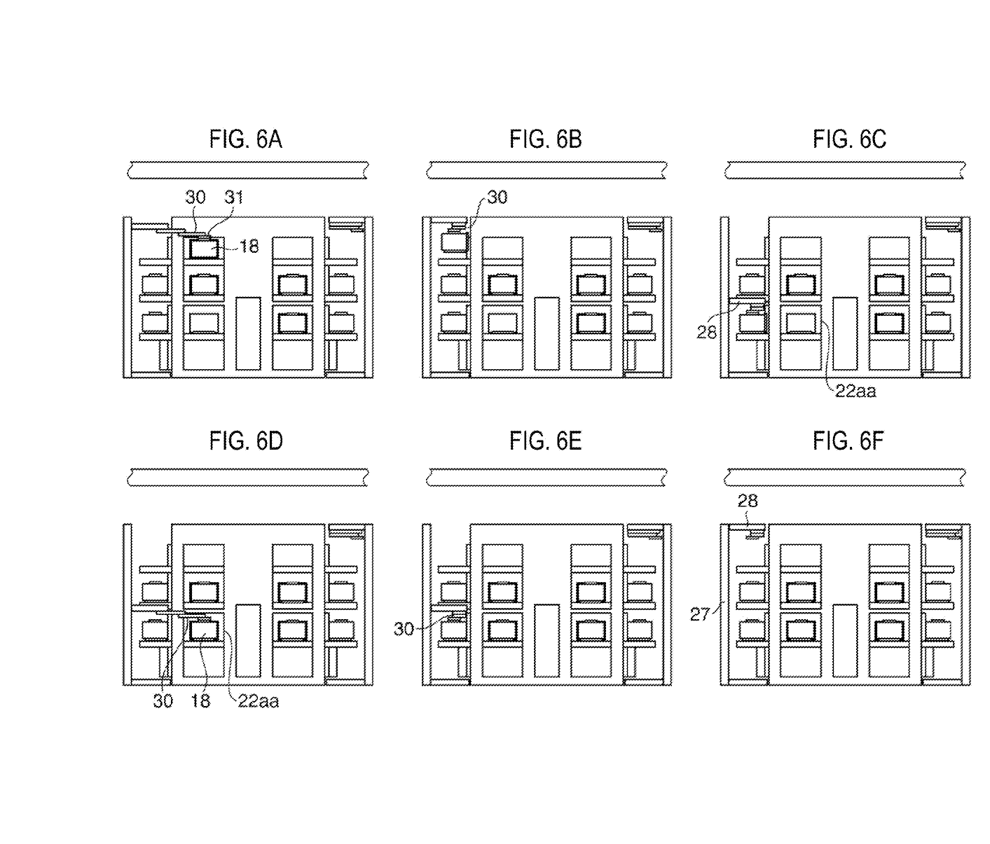

Then, the arm 30 of the FOUP transporter 26 extends, and the coupling part 31 is caught and coupled to the upper portion of the unprocessed FOUP 18 (FIG. 6A). The arm 30 is retracted (FIG. 6B), the base 28 is also lowered to the neighborhood of the lower loading port 22aa (FIG. 6C), and the arm 30 extends to connect the unprocessed FOUP 18 to the FOUP connection port 24 of the lower loading port 22aa (FIG. 6D).

Subsequently, the arm 30 is retracted (FIG. 6E) and the base 28 is also raised to the neighborhood of the upper end of the post 27 (FIG. 6F). Then, this interchanging method is terminated.

According to the container interchanging method of this embodiment, the OHT 38 collects the processed FOUP 18 from the port 25a which is closer to the OHT 38 than the lower loading port 22aa, and the unprocessed FOUP 18 is also mounted in the port 25a. Thus, it is not necessary for the OHT 38 to extend the hoist belt 39 to the lower loading port 22aa. Accordingly, the time necessary for interchanging the processed FOUP 18 and the unprocessed FOUP 18 can be reduced. Consequently, it is possible to prevent manufacturing efficiency of semiconductor devices from being deteriorated.

Subsequently, a container interchanging method according to a second embodiment of the present disclosure will be described with reference to the drawings. Since this embodiment is basically the same as the above-described first embodiment in its configuration and functions, redundant description will be omitted and only the following differences will he described.

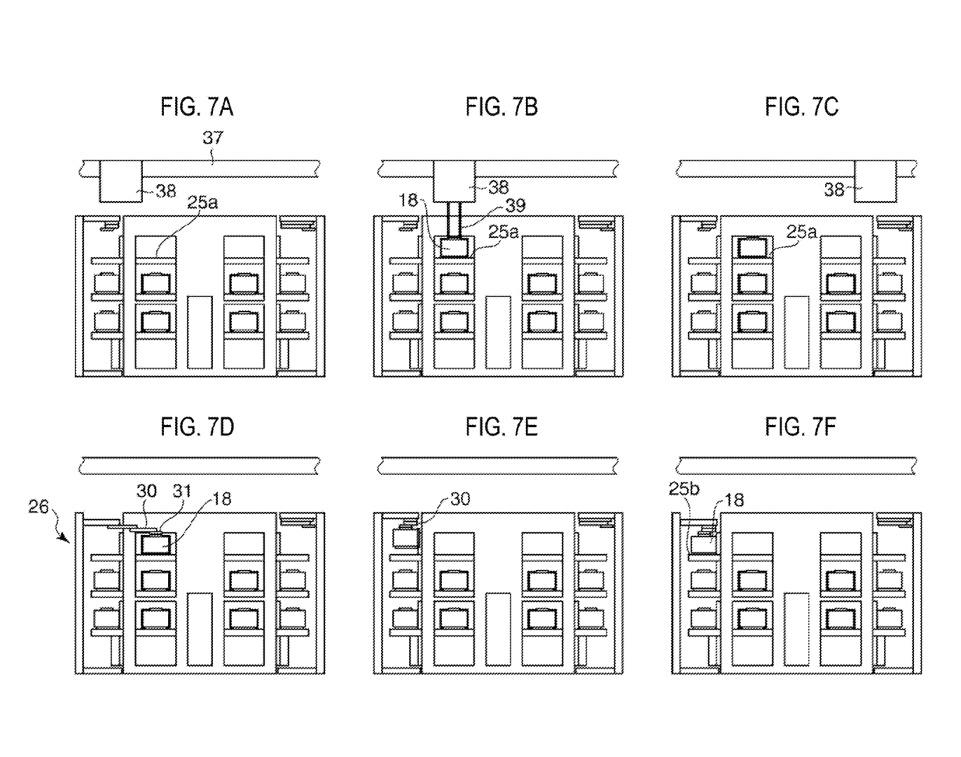

FIGS. 7A to 9B are process views of a FOUP interchanging method as the container interchanging method according to this embodiment. In this interchanging method, the FOUP transporter 26 and the ceiling container transfer system 36 also cooperate with each other.

First, the OHT 38 transferring the unprocessed FOUP 18 moves along the guide rail 37 (FIG. 7A) and stops at the point above the port 25a. The hoist belt 39 is lowered from the OHT 38 and mounts the unprocessed FOUP 18 in the port 25a to temporarily store the unprocessed FOUP 18 in the port 25a (FIG. 7B).

Thereafter, the OHT 38 hoists the hoist belt 39 and is withdrawn from the point above the port 25a (FIG. 7C). The ID reader 33 of the port 25a reads the processing information written in the ID unit 32 of the unprocessed FOUP 18 temporarily stored in the port 25a. Here, the ID reader 33 transmits the read processing information to a control unit of the substrate processing system 10. The control unit performs a dummy process corresponding to the processing information read in the process module 13a or the like using a dummy wafer.

Subsequently, the arm 30 of the FOUP transporter 26 extends and the coupling part 31 is caught and coupled to the upper portion of the unprocessed FOUP 18 (FIG. 7D). The arm 30 is retracted (FIG. 7E) and also mounts the unprocessed FOUP 18 in the buffer 25b to temporarily store the unprocessed FOUP 18 in the buffer 25b (FIG. 7F).

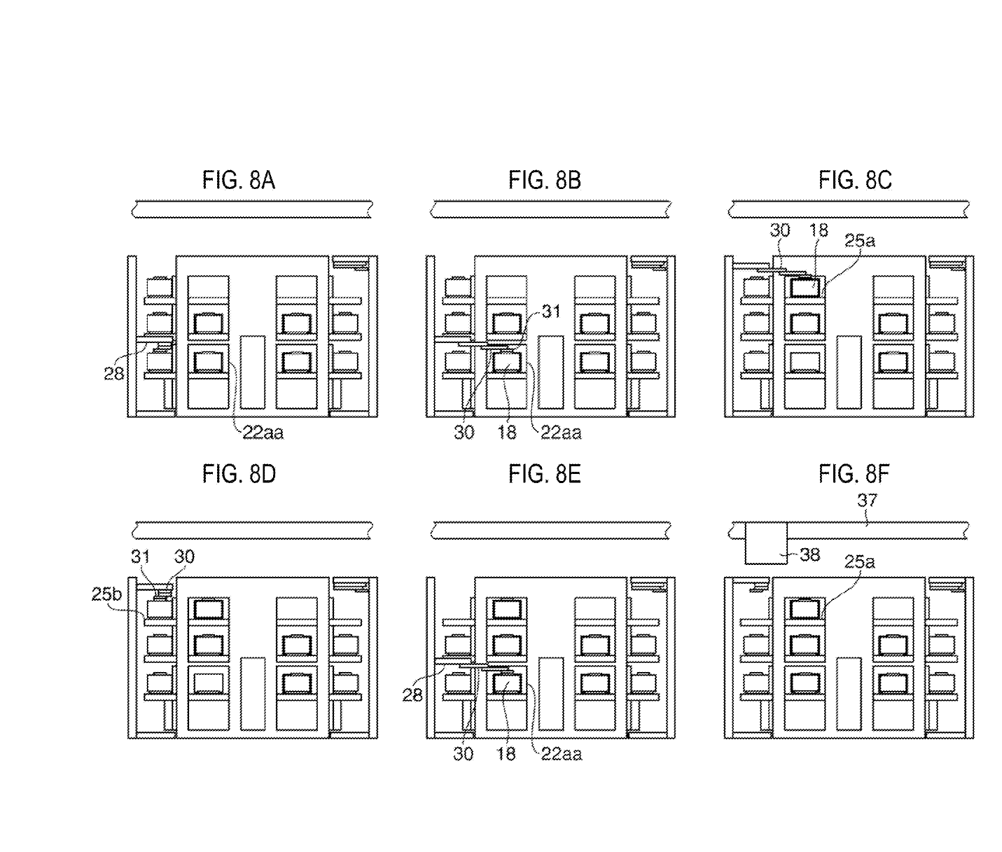

Subsequently, the base 28 is lowered to the neighborhood of the lower loading port 22aa (FIG. 8A), the arm 30 extends, and the coupling part 31 is caught and coupled to the upper portion of the processed FOUP 18 connected to the FOUP connection port 24 of the lower loading port 22aa (FIG. 8B).

Successively, as the arm 30 is retracted and the base 28 is raised to the neighborhood of the port 25a, the processed FOUP 18 is removed from the lower loading port 22aa. The arm 30 also extends and mounts the processed FOUP 18 in the port 25a to temporarily store the processed FOUP 18 in the port 25a (FIG. 8C).

Successively, the arm 30 is retracted, and the coupling part 31 is caught and coupled to the upper portion of the unprocessed FOUP 18 mounted in the buffer 25b (FIG. 8D). The base 28 is lowered to the neighborhood of the lower loading port 22aa, and the arm 30 extends to connect the unprocessed FOUP 18 to the FOUP connection port 24 of the lower loading port 22aa (FIG. 8E).

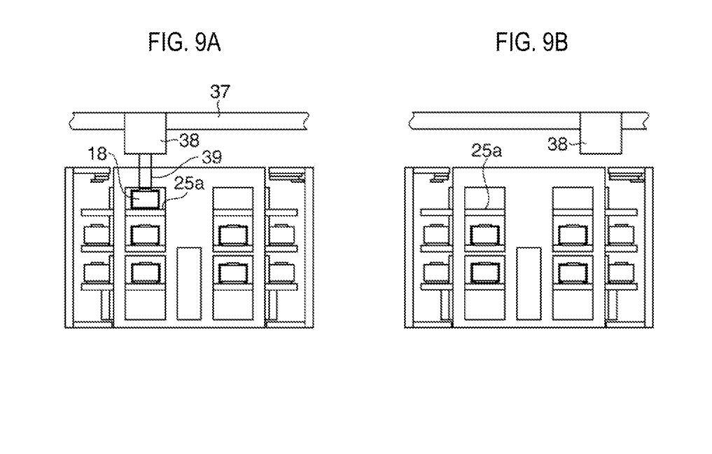

Successively, the OHT 38 moves along the guide rail 37 (FIG. 8F) and stops at the point above the port 25a. The hoist belt 39 is lowered from the OHT 38 and caught and coupled to the upper portion of the processed FOUP 18 (FIG. 9A). The OHT 38 hoists the hoist belt 39, accommodates the processed FOUP 18 therein, and is withdrawn from the point above the port 25a (FIG. 9B). Then, this interchanging method is terminated.

According to the container interchanging method of this embodiment, when the processed FOUP 18 and the unprocessed FOUP 18 are interchanged in the lower loading port 22aa, the unprocessed FOUP 18 is temporarily stored in the buffer 25b, the processed FOUP 18 is removed from the lower loading port 22aa, and then, the unprocessed FOUP 18 temporarily stored in the buffer 25b is transported to the lower loading port 22aa. Thus, after the processed FOUP 18 is removed from the lower loading port 22aa, until the OHT 38 transferring the unprocessed FOUP 18 moves to the point above the lower loading port 22aa and transports the unprocessed FOUP 18 to the lower loading port 22aa, the need for the lower loading port 22aa to wait can be eliminated. Consequently, it is possible to reduce the waiting time of the lower loading port 22aa and thus to prevent the manufacturing efficiency of semiconductor devices from being deteriorated.

Further, in the conventional substrate processing system, since the ID reader is provided in the loading port, after the FOUP is transported to the loading port, the ID reader reads the processing information written in the ID unit of the FOUP. Thus, a dummy process corresponding to the read processing information can be initiated only after the FOUP is transported to the loading port.

In the meantime, according to the container interchanging method of this embodiment, before the unprocessed FOUP 18 is transported to the lower loading port 22aa, the ID reader 33 of the port 25a reads the processing information written in the ID unit 32 of the unprocessed FOUP 18. Thus, the dummy process corresponding to the read processing information can be initiated before the unprocessed FOUP 18 is transported to the lower loading port 22aa. Also, after the unprocessed FOUP 18 is transported to the lower loading port 22aa, a plasma process on the respective wafers W accommodated in the unprocessed FOUP 18 can be immediately initiated.

That is, according to the container interchanging method of this embodiment, the ID reader 33 reads the processing information written in the ID unit 32 of the unprocessed FOUP 18 temporarily stored in the port 25a. Thus, it is possible to eliminate the need to read the ID unit 32 of the unprocessed FOUP 18 due to the provision of the ID reader in the loading port 22. Also, it is possible to reduce the waiting time until the plasma process on the wafers W accommodated in the unprocessed FOUP 18 transported to the loading port 22 is initiated. Accordingly, it is possible to prevent manufacturing efficiency of semiconductor devices from being deteriorated.

Next, a container interchanging method according to a third embodiment of the present disclosure will be described with reference to the drawings. Since this embodiment is basically the same as the above-described first embodiment in its configuration and functions, redundant description will be omitted and only the following differences will be described.

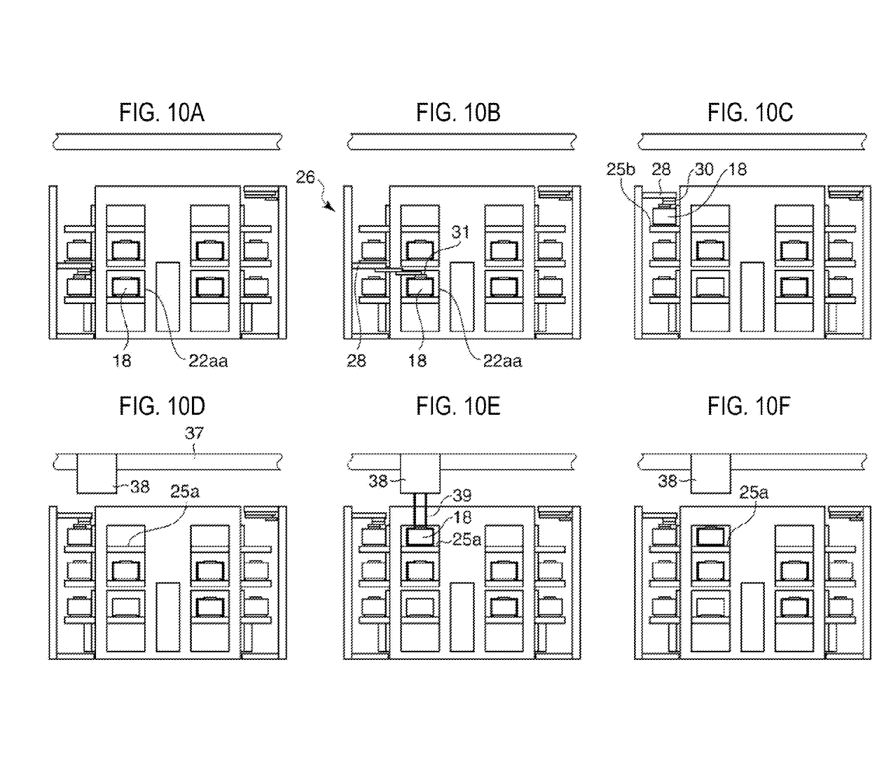

FIGS. 10A to 12 are process views of a FOUP interchanging method as the container interchanging method according to this embodiment. In this interchanging method, the FOUP transporter 26 and the ceiling container transfer system 36 also cooperate with each other.

First, if the plasma process on all the wafers W accommodated in the FOUP 18 connected to the FOUP connection port 24 of the lower loading port 22aa is terminated, the base 28 of the FOUP transporter 26 is lowered to the neighborhood of the lower loading port 22aa (FIG. 10A). The arm 30 then extends to the processed FOUP 18 connected to the FOUP connection port 24 of the lower loading port 22aa and the coupling part 31 is caught and coupled to the upper portion of the processed FOUP 18 (FIG. 10B).

Subsequently, the arm 30 is retracted, and the base 28 is raised to the neighborhood of the buffer 25b to mount the processed FOUP 18 in the buffer 25b and temporarily store the processed FOUP 18 in the buffer 25b (FIG. 10C). Here, the purge unit 34 of the buffer 25b purges the interior of the FOUP 18 temporarily stored in the buffer 25b using N₂ gas.

Subsequently, the OHT 38 transferring the unprocessed FOUP 18 moves along the guide rail 37 (FIG. 10D) and stops at the point above the port 25a. The hoist belt 39 is lowered from the OHT 38 and mounts the unprocessed FOUP 18 in the port 25a to temporarily store the unprocessed FOUP 18 in the port 25a (FIG. 10E).

Thereafter, the OHT 38 hoists the hoist belt 39 and waits at the point above the port 25a (FIG. 10F). The ID reader 33 of the port 25a reads the processing information written in the ID unit 32 of the unprocessed FOUP 18 temporarily stored in the port 25a. Here, in the same manner as the second embodiment, the ID reader 33 transmits the read processing information to a control unit of the substrate processing system 10. The control unit performs a dummy process corresponding to the processing information read in the process module 13a or the like using a dummy wafer.

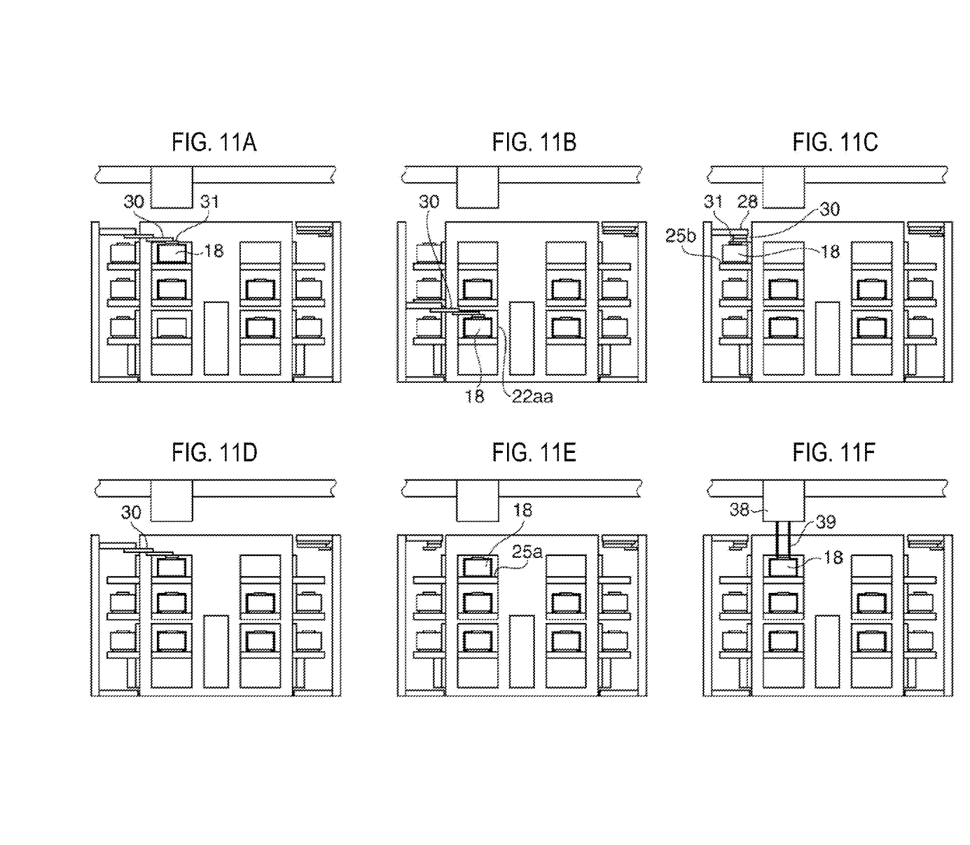

Subsequently, the arm 30 extends, and the coupling part 31 is caught and coupled to the upper portion of the unprocessed FOUP 18 (FIG. 11A). The arm 30 is retracted, the base 28 is lowered to the neighborhood of the lower loading port 22aa, and the arm 30 also extends to connect the unprocessed FOUP 18 to the FOUP connection port 24 of the lower loading port 22aa (FIG. 11B).

Successively, the arm 30 is retracted, the base 28 is raised to the neighborhood of the buffer 25b, and the coupling part 31 is caught and coupled to the upper portion of the processed FOUP 18 (FIG. 11C). Then, the arm 30 extends (FIG. 11D) to mount the processed FOUP 18 in the port 25a to temporarily store the processed FOUP 18 in the port 25a (FIG. 11E).

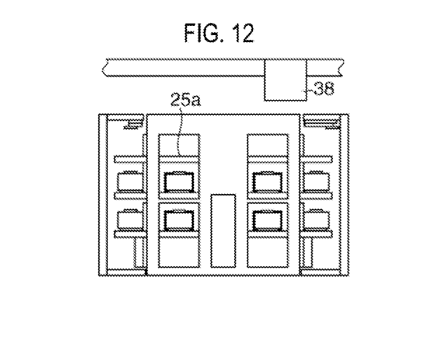

Successively, the hoist belt 39 is lowered from the waiting OHT 38 and caught and coupled to the upper portion of the processed FOUP 18 (FIG. 11F). The OHT 38 hoists the hoist belt 39, accommodates the processed FOUP 18 therein, and is withdrawn from the point above the port 25a (FIG. 12). Then, this interchanging method is terminated.

According to the container interchanging method of this embodiment, when the processed FOUP 18 and the unprocessed FOUP 18 are interchanged in the lower loading port 22aa, after the processed FOUP 18 is temporarily stored in the buffer 25b, the unprocessed FOUP 18 is transported to the lower loading port 22aa. Accordingly, until the OHT 38 moves to the point above the lower loading port 22aa and the processed FOUP 18 is removed from the lower loading port 22aa, it is possible to eliminate the need for the lower loading port 22aa to wait for the transport of the unprocessed FOUP 18 to the lower loading port 22aa. Consequently, it is possible to reduce the waiting time of the lower loading port 22aa and thus to prevent manufacturing efficiency of semiconductor devices from being deteriorated.

Further, in the ceiling container transfer system 36, in many cases, a stocker (not shown) storing a plurality of the FOUPs 18 is disposed at a place away from the substrate processing system 10. Thus, if the OHT 38 frequently moves in order to transport the FOUPs 18, a throughput is deteriorated. However, since in this interchanging method, the OHT 38 waits at the point above the port 25a, the frequent movement of the OHT 38 can be suppressed to prevent a throughput from being deteriorated.

However, in the conventional substrate processing system, the purge unit is provided in the loading port. Thus, before a FOUP accommodating the processed wafers W therein is removed from the loading port, the interior of the FOUP (processed FOUP) is purged by the purge unit. Therefore, the removal of the processed FOUP can be initiated only after the interior of the processed FOUP is purged by the purge unit.

In the meantime, according to the container interchanging method of this embodiment, the purge unit of the buffer 25b purges the interior of the processed FOUP 18 temporarily stored in the buffer 25b. Thus, it is possible to eliminate the need to purge the interior of the processed FOUP 18 in the lower loading port 22a. Consequently, the time until the processed FOUP 18 accommodates the processes wafers W therein and is removed from the lower loading port 22a can be reduced, and thus, manufacturing efficiency of semiconductor devices can be prevented from being deteriorated.

In addition, in the conventional substrate processing system, after the FOUPs are transported to the respective loading ports, a process of loading a dummy wafer into the process module (hereinafter, referred to as a “process A”), a dummy process using the dummy wafer (hereinafter, referred to as a “process B”), a plasma process on the respective wafers (for example, a plasma process on 25 sheets of wafers as one lot) (hereinafter, referred to as a “process C”), a process of removing particles by neutralization and introduction of gas in each process module (hereinafter, referred to as a “process D”), a process of loading the plasma-processed wafers into a FOUP (hereinafter, referred to as a “process E”), a process of disconnecting the FOUP from the FOUP connection port (hereinafter, referred to as a “process F”), a process of purging the interior of the FOUP (hereinafter, referred to as a “process G”) and a process of interchanging FOUPs (hereinafter, referred to as a “process H”) are performed. That is, the series of processes (the processes A to H) are performed in the loading ports, and for the meantime, no FOUP can be withdrawn from the loading ports.

For example, in the loader module having seven loading ports (LP1 to LP7), the above-described series of processes are performed in each loading port. However, since the processes A and E or the like are performed by the single transfer robot of the loader module, the processes A and E cannot be simultaneously performed in the plurality of loading ports.

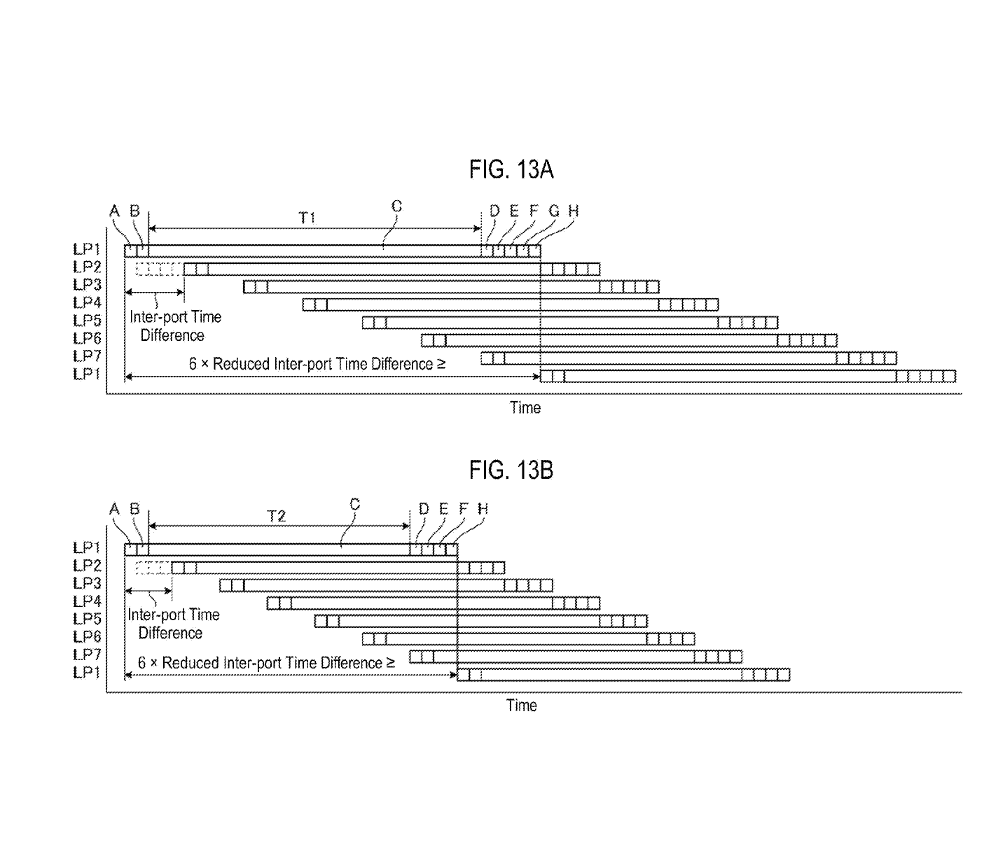

Therefore, in the conventional substrate processing system, as shown in FIG. 13A, after the process A is performed in a loading port LP1 using the transfer robot. Then, the process E on a FOUP of a previous lot (see the broken line in the figure) is performed in another loading port LP2 using the transfer robot. Successively, the processes F to H on the FOUP of the previous lot (see the broken line in the figure) are performed in the other loading port LP2. Thereafter, at last, the process A on the FOUP of the next lot is performed in the other loading port LP2. That is, the series of processes in each loading port are performed with a time difference (hereinafter, referred to as an “inter-port time difference”) which is necessary for the processes A and E to H.

When there are the seven loading ports as described above, from the initiation of the series of processes on the FOUP of the previous lot to the initiation of the series of processes on the FOUP of the next lot in the same loading port, at least six times of the inter-port time difference are needed. However, in other words, even if the time necessary for the series of processes is reduced by reducing the time necessary for the plasma process (by reducing the process C), the FOUP cannot be withdrawn unless the time six times of the inter-port time difference elapses in each loading port.

In the meantime, in the same manner as the container interchanging method according to this embodiment, if the need to purge the interior of the processed FOUP 18 is eliminated in the lower loading port 22a, the above-described process G can be omitted. Thus, as shown in FIG. 13B, if after the process A is performed in one loading port 22, LP1, using the transfer robot, the process E on the FOUP 18 of the previous lot (see the broken line in the figure) is performed in another loading port 22, LP2, using the transfer robot, and the processes F and H on the FOUP 18 of the previous lot (see the broken line in the figure) are performed in the other loading port 22, LP2, the process A on the FOUP 18 of the next lot can be performed in the other loading port 22, LP2. That is, the inter-port time difference can be reduced by the time for the process G. In addition, hereinafter, the inter-port time difference reduced by the time for the process G is referred to as the “reduced inter-port time difference.”

Here, in the container interchanging method according to this embodiment, in the same loading port 22, from the initiation of the series of processes on the FOUP 18 of the previous lot to the initiation of the series of processes on the FOUP 18 of the next lot, the time six times of the reduced inter-port time difference is needed. In other words, even though the time necessary for the plasma process is reduced until it corresponds to six times of the reduced inter-port time difference in each loading port 22 (even though the process C is reduced) (see T1 and T2 in the figure), a situation where the FOUP 18 cannot be withdrawn does not occur.

That is, according to the container interchanging method of this embodiment, it is possible to reduce the time necessary for the plasma process in consideration of the withdrawal of the FOUP 18 from the loading port 22.

For example, it was seen from an inventors' simulation that if the time necessary for the process G was 100 seconds, by using the container interchanging method according to this embodiment, the time necessary for the plasma process could be reduced from 58.9 seconds to 36.6 seconds in some processing conditions. In other processing conditions, the time necessary for the plasma process could be reduced from 43.2 seconds to 41.7 seconds.

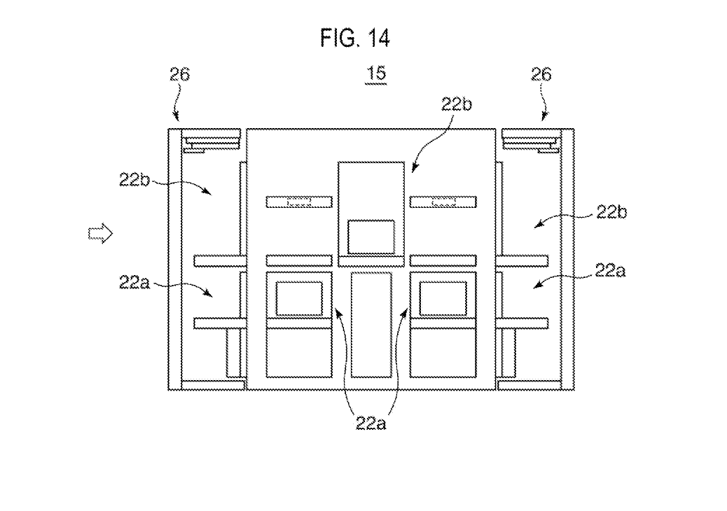

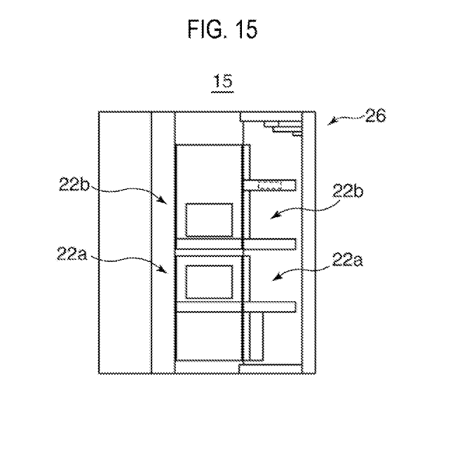

For example, the loader module 15 needs not to have the eight loading ports 22, and the number of the loading ports 22 should be at least more than only the number of the process modules 13. For example, as shown in FIGS. 14 and 15, the loader module 15 may be provided with seven loading ports 22. In such a case, although two of the lower loading ports 22a and one of the upper loading ports 22b are disposed in the side 21a, the container interchanging method according to the above-described embodiments can be performed in such a loader module 15.

According to the present disclosure, when the first container and the second container are interchanged in the container connection mechanism, after the second container is temporarily stored in the buffer, the first container is removed from the container connection mechanism. Then, the second container temporarily stored in the buffer is transported to the container connection mechanism. Thus, it is possible to eliminate the need for the container connection mechanism to wait for the container transporter, until the container transporter moves to the point above the container connection mechanism after the first container is removed from the container connection mechanism.

According to the present disclosure, when the first container and the second container are interchanged in the container connection mechanism, after the first container is temporarily stored in the buffer, the second container is transported to the container connection mechanism. Thus, it is possible to eliminate the need for the container connection mechanism to wait for the container transporter to transport the second container to the container connection mechanism, until the container transporter moves to the point above the container connection mechanism after the first container is removed from the container connection mechanism.

Consequently, it is possible to reduce the waiting time of the container connection mechanism and thus to prevent the manufacturing efficiency of semiconductor devices from being deteriorated.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A container interchanging method comprising:
when interchanging a first container, into which a processed substrate is accommodated, and a second container, into which an unprocessed substrate is accommodated, in a container connection mechanism of a substrate transfer chamber, the substrate transfer chamber further including a buffer configured to mount the first or second container,
storing the first or second container in the buffer temporarily,
wherein the substrate transfer chamber includes the container connection mechanism to which the first or second container is connected, the substrate transfer chamber being configured to unload the processed or unprocessed substrate from the first or second container connected to the container connection mechanism.

2. The method of claim 1, wherein the substrate transfer chamber further includes a container transporter configured to transport the first or second container to the container connection mechanism, and when the container transporter transports the second container to the container connection mechanism, the first container is temporarily stored in the buffer.

3. The method of claim 2, wherein the buffer has a purge unit configured to purge an interior of the container, and the purge unit purges an interior of the first container temporarily stored in the buffer.

4. The method of claim 1, wherein the substrate transfer chamber further includes a container transporter configured to transport the first or second container to the container connection mechanism, and when the container transporter removes the first container from the container connection mechanism, the second container is temporarily stored in the buffer.

5. A container interchanging method comprising:
when interchanging a first container, into which a processed substrate is accommodated, and a second container, into which an unprocessed substrate is accommodated, in a container connection mechanism of a substrate transfer chamber, the substrate transfer chamber further including a port configured to receive the first or second container from a container transfer mechanism installed in addition to the substrate transfer chamber,
storing the first or second container in the buffer temporarily,
wherein the substrate transfer chamber includes the container connection mechanism to which the first or second container is connected, the substrate transfer chamber being configured to unload the processed or unprocessed substrate from the first or second container connected to the container connection mechanism.

6. The method of claim 5, wherein the second container includes an identification unit showing processing information indicating whether the first or second container includes the processed substrates or the unprocessed substrate,
the port includes a reading unit configured to read the identification unit, and
the reading unit reads the identification unit of the second container temporarily stored in the port.
